(19) United States
(12) Patent Application Publication
(10) Pub. No.: US 2006/0103590 A1
(43) Pub. Date: May 18, 2006

(54) Augmented display system and methods

(76) Inventor: Avner Divon, Rosh Haayin (IL)

Correspondence Address: Avner Divon, 5 Gefen street, P.O.B. 4660, Rosh Haayin, 48570, IL

(21) Appl. No.: 11/253,660

(22) Filed: Oct. 20, 2005

Related U.S. Application Data
(60) Provisional application No. 60/620,558, filed on Oct. 21, 2004.

(51) Int. Cl. G09G 5/00; G03H 1/00; H05K 11/00; G02B 27/14; G08B 3/00

(52) U.S. Cl. 345/7; 345/633; 359/13; 359/630; 340/691.6; 455/344

(57) ABSTRACT

A mobile augments information system with capabilities of displaying information within field of view of the eyes a vehicle operator. The mobile augments information system includes a Head Up Display (HUD) apparatus consisting of a projector, a selectively reflecting visor and a HUD processing units. The Mobile HUD displays digital information that may be received from external sources such as a cellular phone, navigation system, automotive system, or remote information systems such as Location Based Services (LBS). The data may be received via a wireless link, or a wired link. The mobile HUD may be controlled locally, remotely by a vehicle operator using a wireless remote controller, or using voice commands. The mobile HUD system may also include internal information sources, such as a GPS receiver, or a cellular phone. The mobile augments information system can display textual and graphical information using monochrome or multicolor. Visor may be fixed or dynamically controlled.

This application is based on provisional application No. 60/620,558 filed on Oct. 21, 2004

### FIELD OF THE INVENTION

The present invention relates to augmented display of mobile head up display generally.

### BACKGROUND OF THE INVENTION

The following U.S. patents are believed to represent the current state of the art:

| | | |
|---|---|---|
| 6,866,918 3/2005 | Sauer | 428/172 |
| 6,927,674 8/2005 | Harter, Jr. et al. | 340/425.5 |
| 6,922,267 7/2005 | Endo et al. | 359/15 |
| 6,947,875 9/2005 | Winkler, et al. | 703/1 |
| 6,815,680 11/2004 | Kormos | 250/330 |
| 6,837,581 1/2005 | Raines, et al. | 353/13 |
| 6,847,336 1/2005 | Lemelson, et al. | 345/8 |
| 6,664,945 12/2003 | Gyde, et al. | 345/156 |
| 6,567,014 5/2003 | Hansen, et al. | 340/980 |
| 6,718,187 4/2004 | Takagi, et al. | 455/569.2 |
| 6,750,832 6/2004 | Kleinschmidt | 345/7 |
| 6,720,938 4/2004 | Ohkawara, et al. | 345/7 |
| 6,865,460 3/2005 | Bray, et al. | 701/36 |
| 6,731,436 5/2004 | Ishii, et al. | 359/630 |
| 6,771,403 8/2004 | Endo, et al. | 359/13 |
| 6,897,892 5/2005 | Kormos | 348/148 |
| 6,359,737 3/2002 | Stringfellow | 359/631 |
| 6,292,305 9/2001 | Sakuma, et al. | 359/649 |
| 6,262,848 7/2001 | Anderson, et al. | 359/630 |
| 6,445,506 9/2002 | Eccles | 359/631 |
| 6,559,761 5/2003 | Miller, et al. | 340/435 |
| 6,906,836 6/2005 | Parker, et al. | 359/15 |

### SUMMARY OF THE INVENTION

The current invention provides augmented information on the go while reducing the hazards and risks that are related to using personal communication and computing devices while driving a vehicle. People are spending significant time within cars. In many cases using personal communicating and computing devices while driving force the driver's eyes off the road in order to watch information such as caller identification of a received cellular phone, viewing and flipping through a mobile address book before making a call, watch driving directions, view maps, or receive a textual, pictorial, or multimedia messages and information.

The Head-up Display (HUD) systems are well known and are being used for various mobile applications. Current invention diminishes at least some of the disadvantages associated with methods and solutions for displaying mobile and cellular information in a mobile environment. It enables Head-up Display (HUD) systems to be easily and seamlessly utilized with mobile applications.

Addressing the hazards of using cell phones while driving, modern car kits offer today wide remote LCD displays that are installed on the dashboard to enable the driver to view the cell phone parameters such as his address book with minimal diverting of his eyes. The large remote LCD display has not solved the need of the driver for changing his eyes focus from long to short range and visa versa, the need to view that data in a different light conditions and the additional eyes focus diversion all these components maintain the risk of using a cell phone while driving even with a large remote display.

Some lucrative cars have built in HUD systems that are wired to built in car systems such as Infra red imaging and navigation systems. Most cars do not have such HUD systems. Adding a HUD to a car would require complicated hardware and software interface and expensive wiring that would enable the HUD system to communicate and display a personal communicator data.

In one embodiment of present invention, a system that provides a vehicle's driver with, an augmented information and data within his Field-Of-View (FOV). The augmented information is wirelessly received from the driver's communicating or computing apparatus. Such a wireless apparatus can be a cell phone, a PDA, an infotainment (information-entertainment) system, a mobile computer, or a navigation system, or another infotainment (information-entertainment) system, such as satellite radio (i.e. XM-radio)

It would be appreciated that current invention provides seamless connectivity between the personal, portable communicating or mobile computing apparatus and a wireless HUD, which enable vehicle's drivers to easily and safely utilize their handheld communicating and computing devices while in the car and without taking their eyes off the road.

In another embodiment of present invention, a HUD that received image information from a portable computing or communicating apparatus and automatically reformats the images, text or video to match it to the HUD optical properties such as resolution and image size.

It would be appreciated that current invention enables seamless ubiquitous connectivity of the wireless HUD of current invention to most personal wireless communicators and portable computers. As a result layman would easily be able to install the wireless HUD and safely use it and by doing so, would increase safety driving. The wireless installation requires no wires and will keep the driver space free of wires.

In another embodiment of current invention is the HUD capabilities of getting into the drivers FOV on demand only and its ability to be dismissed on demand or on sever event such as a car collision. Yet in another embodiment of current invention is the HUD capability to automatically adjust the projected image intensity to match the visual conditions in the user's FOV

In another embodiment of current invention is the wireless HUD is connected to personal portable GPS enabling these portable devices to safely display augmented data such as maps and driving directions to the driver within his FOV and without taking his eyes off the road.

In another embodiment of current invention is the wireless HUD is wearable and is wirelessly connected to computing apparatuses such as personal computer, or infotainment (information-entertainment) system, or personal communicators or servers, enabling the user to wirelessly receive and augmented watch data and information that is received from these devices without the need to carry computers with him while performing his job and while enabling use both his hands for his tasks.

### BRIEF DESCRIPTION OF THE DRAWINGS

The present invention will be understood and appreciated more fully from the following detailed description, taken in conjunction with the drawings in which:

FIG. 1 is a simplified partially pictorial functional block diagram illustrating a preferred embodiment of the present invention, including a wireless Head Up Display in connection with wireless communicator and a wireless network.

FIG. 2 is a simplified functional block diagram, illustrating various implementations of the functionality of FIG. 1.

FIG. 3 is a simplified functional block diagram, illustrating another implementation of the functionality of FIGS. 1, 5, and 7;

FIG. 4 is a simplified functional block diagram, illustrating various implementation aspects of the functionality of FIGS. 1, 5, and 7.

FIG. 5 a simplified partially pictorial functional block diagram illustrating another preferred embodiment of the present invention.

FIG. 7A a simplified partially pictorial functional block diagram illustrating another preferred embodiment of the present invention.

FIG. 7B a simplified partially pictorial functional block diagram illustrating another preferred embodiment of the present invention.

FIGS. 7C, D, E are pictorial views illustrating various implementation aspects of preferred embodiments of the present invention.

FIG. 10 a simplified partially pictorial functional block diagram illustrating a wearable HUD in connection with a mobile communicator.

FIG. 11 a simplified partially pictorial functional block diagram illustrating a wearable HUD in connection with a wireless network.

FIG. 12 is a simplified functional block diagram, illustrating various implementation aspects of the functionality of FIGS. 10, 11.

FIG. 13 A, B, C, are simplified partially pictorial functional block diagrams illustrating some preferred embodiments of the present invention, including possible mechanical description.

FIG. 14 a simplified partially pictorial functional block diagram illustrating a mobile HUD in connection with input means.

FIG. 15 a simplified partially pictorial functional block diagram illustrating a mobile HUD in connection with various implementation aspects of input means.

FIG. 16 is a simplified functional block diagram, illustrating various implementation aspects of a monochrome mobile HUD.

FIG. 17A, is a simplified functional block diagram, illustrating various preferred implementation aspects of a color mobile HUD. FIG. 17B is a simplified flow-chart illustrating operation of the functionality shown in respective FIG. 17A.

FIG. 18A, B, C, are simplified functional block diagram, illustrating implementation aspects of another preferred embodiment of a color mobile HUD of current invention.

FIGS. 20A, B are a simplified partially pictorial functional block and flow diagrams illustrating preferred embodiments of the present invention, including a multiplicity of communicators in wireless and IP communication with a plurality of information servers centers and involving a mobile HUD of present invention.

FIG. 21 is a simplified flow-chart illustrating operation of the functionality shown in respective FIGS. 20A, B.

FIG. 24A is a simplified functional block diagram, illustrating implementation aspects of another preferred embodiment of a wireless apparatus with a built in HUD of current invention. FIG. 24B is a pictorial view of one possible implementation of FIG. 24A.

FIG. 25 A, B, C, D, E, F, G, H, I are simplified partially pictorial functional block diagrams illustrating some preferred embodiments of the present invention, including possible mechanical description.

### DETAILED DESCRIPTION OF PREFERRED EMBODIMENTS

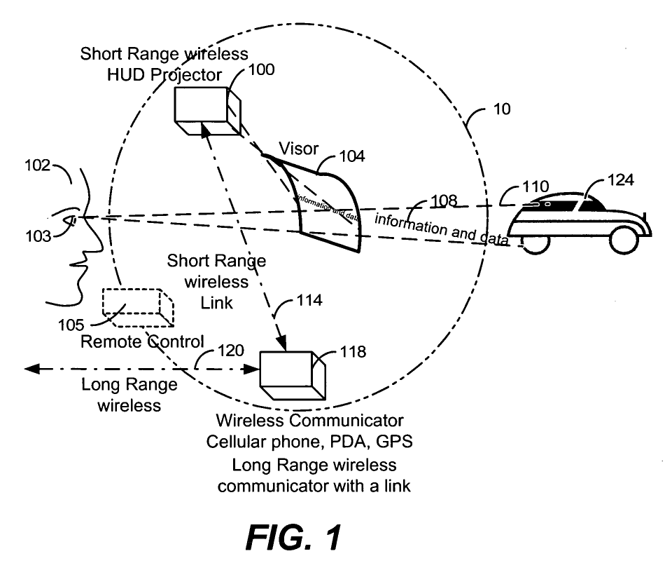

Reference is now made to FIG. 1, which is a simplified partially pictorial functional block diagram illustrating a preferred embodiment of the present invention, including a wireless Head Up Display (HUD) operating in plurality of communication wireless networks.

The illustrated embodiment of FIG. 1 is presented in the context of cellular communications in a car, it is understood that this embodiment of the invention is not limited to cellular communications and is equally applicable to other suitable types of wireless communications networks and other vehicles and mobile applications.

In FIG. 1, a Wireless Head Up Display (HUD) system 10 for providing augmented information 108 that is projected in front of a vehicle's operator 102 and within his field of view 110.

A long-range communicator device 118 such as a cellular phone, a wireless PDA, or an infotainment (information-entertainment) system, wireless computing apparatus, a GPS, or a satellite communicator, or radio device is located within the vehicle cabinet. The communicator device 118 is long-range wirelessly connected 120 with a wireless network. Such long-range wireless connection 120 of current invention may be cellular network such as GSM, CDMA, GPRS, UMTS, WCDMA, 3G, 4G, or Wi-Fi, WiMax, satellite, GPS, and other long-range RF networks, satellite communication, digital terrestrial, or satellite TV and radio, such as XM radio, special and proprietary wireless networks and new communication networks.

Information which the vehicle's operator 102 needs is wirelessly transferred using a short range wireless link 114 to the Wireless Head Up Display (HUD) projector 100 that may be located near the vehicle's windshield. It can be attached or within the vehicle sun visor, or can be attached or within vehicle's dashboard, or attached to the windshield itself, or attached or within the vehicle back mirror. The information received is than processed within the HUD projector unit 100 to match its internal projector's image format. The image is than projected onto a visor reflector/lens 104. The vehicle operator 102 can than view a superimposing of a virtual image 108 within a field-of-view (FOV) 110 on a front view looked through a windshield from an eye point 103 within the vehicle. The short range wireless link 114 may be Bluetooth, Wi-Fi, WiMax, NFC, UWB, Zigbee, or proprietary RF link such as RFWaves/Vishay, optical link, or a serial link such as USB, RS232, or similar. A remote Control 105 may be used to control the Operation of the Head Up Display (HUD) projector 100.

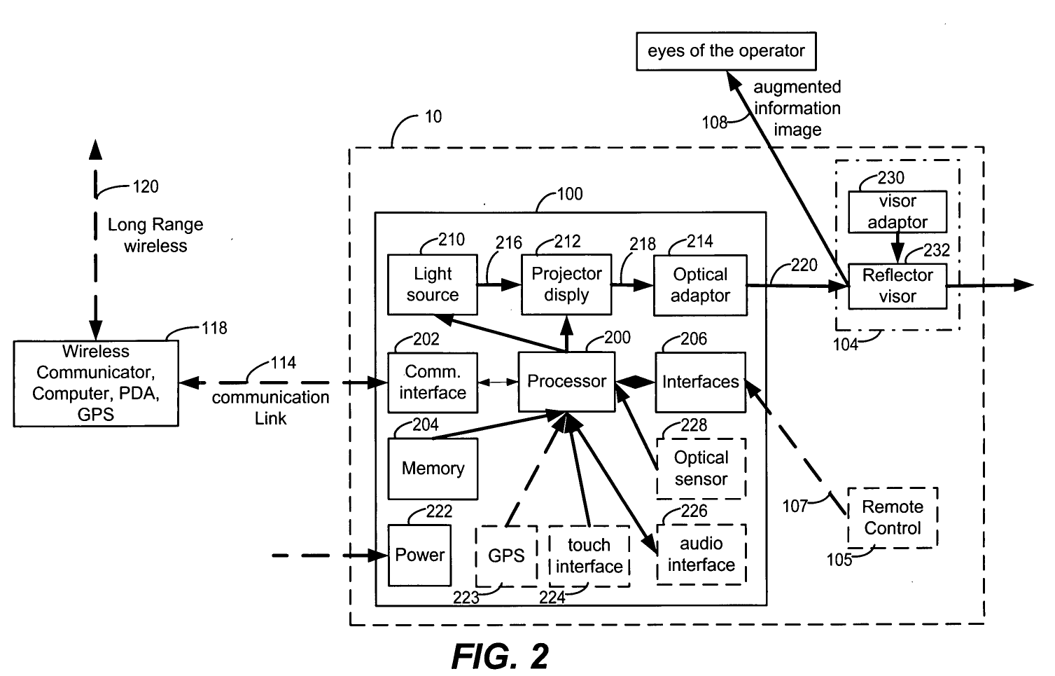

Reference is now made to FIG. 2 which is a simplified functional block diagrams illustrating various implementations of the functionality of FIG. 1. FIG. 2 shows a block diagram of one possible structure of a Wireless Head Up Display (HUD) 10 system of current invention. A HUD Projector unit 100 comprises of a Processor 200, which manages HUD activities. The Processor unit 200 may be a simple MCU such as 8051, an ARM, a RISC or a DSP, or a special ASIC. The Processor unit 200 manages the communication with a wireless communicator 118 which may be a personal, or vehicle communicator such as a cellular phone, a portable, or mobile computer, a PDA, a GPS, or an infotainment (information-entertainment) system, a radio/TV receiver. A communication link 114 connects between the communicator 118 and the HUD Projector unit 100. Such a communication link 114 of current invention is preferably a short-range wireless. Such a short-range wireless communication link 114 may be RF link such as Bluetooth, Wi-Fi, NFC, UWB, WiMax, Zigbee or proprietary RF such as RFWaves/Vishay, Chipcon, and Nordic. Alternative wireless link can be IR such as IrDA. A Communication interface 202 interfaces between the communicator 118 and the HUD processor 200. In case a wireless link is used as the communication link 114, the communication interface 202 is a wireless modem. An alternative embodiment of current invention is a wired link, which can be used as the communication link 114. Such a wired link may be a USB, USB2Go, and serial link such as RS232, parallel link, optical, or a proprietary link.

Processor unit 200 receives images data to be displayed on the HUD. The Processor unit 200 processes this data and prepares it to match the projector display 212 parameters, so it would fit the projector display and the optical system, which comprises the HUD. In some cases, the processor 200 will also compute the adjustments that are needed to correct optical HUD system optical distortions due to lenses, reflectors, and light waves propagation. The image that is generated by the Processor unit 200 is transferred to the Projector display 212. The Projector display 212 may be of a transparent LCD type. A light source and a diffuser 210 radiate light waves 216 through the Projector display 212 and via the optical adaptor 214, that may be only a covering protecting transparent material, or may also has optical transfer function. The projected image light waves 220 are directed to the reflector visor unit 232. The reflector visor unit 232 preferably can be of polycarbonate, a glass, a plastic, acrylic, or other transparent materials. Preferably the visor will be coated with a partly reflecting material, or colored, so it will function as a semi-transparent reflector. The reflector visor unit 232 preferably is shaped with optical gain such as parabolic, aspheric, or other shapes that would provide optical gain. Though it may also have no optical gain. The reflector visor unit 232 is preferably used as a reflecting lens of the projected image while being transparent to the images that are within the Field of view (FOV) of the vehicle operator's eyes 103 of FIG. 1. Alternatively the reflector visor unit 232 may be a foil that is attached to the vehicle's windshield in order to prevent double image, in such implementation there is no optical gain at the visor unit 232. The Visor reflector 232 may also be part of the windshield. It may be embedded within the windshield itself such by using optical materials such as DuPont's Butacite® wedged PVB interlayer. The projected images 108 that are reflected from the reflector visor unit 232 provides the vehicle's operator an augmented image of the images of the information as received from the Communicator 118 to be displayed overlaid with the images, which are within his FOV in front of the Vehicle.

In an alternative embodiment of current invention a Visor reflector 232 which can be attached to the vehicle by a Visor adaptor 230. In such a case the Visor adaptor 230 enables adjustments of the Visor reflector 232 position and angels. Visor reflector 232 may also be detachable. So in case if an emergency situation while an external force which exceeds a certain amount which may endanger the vehicle operator, the Visor reflector 232 will be detached. In an alternative embodiment of current invention a Visor adaptor 230 holds the Visor reflector 232 in a folded position. Upon a defined event the Visor adaptor 230 may position the visor reflector 232 in an “active” position, which is within the FOV of the Vehicle operator. Such an event may be activation of the Communicator 118 such as activation of a cellular phone, receiving a cellular call, searching the address book, dialing or other central unit possible activations. Alternatively the Visor adaptor 230 can be activated by sound command, a remote control command, a touch of the Operator, or external communication event. Upon another defined event, the Visor adaptor 230 may put the Visor reflector 232 at an inactive position such as a folded position. Such events may be a termination of a cellular call. The speed of get in active position, or inactive position may be controlled by the Visor adaptor 230 providing optimized motion that will not be too sudden and not to slow. The HUD Projector unit 100 also comprise of power supply 222, which powers the HUD Projector unit 200. It may also comprise internal power source such as a battery, a rechargeable battery, and may also comprise of a connection to an external power source, such as a cigarette lighter socket. It may also comprise of solar cells for avoiding a connection of the HUD with the vehicle main power supply. It would be appreciated that using solar cells near the windshield would make the system easy to install and add-on existing vehicles.

The HUD Projector unit 100 may also comprise an analog, or digital, or RF interface unit 206. The interface units 206 may be used for communication 107 with a remote control 105 for receiving Operators commands. The remote control 105 may consist of keys and a transmitter for transmitting commands upon pressing these keys. The communication 107 preferably is a wireless such as Bluetooth, Zigbee, or other short range wireless, alternatively it may be a wired communication such as a serial communication.

The HUD Projector unit 100 may also comprise a touch interface 224 which the may be used by the user to activate different functions of the HUD unit 10. Such Touch interfaces 224 may be switches or other touch sensors.

In yet another embodiment of current invention the HUD Projector unit 100 may also comprise a sound interface 226, which enables receiving sound commands from the vehicle operator, or generate sound. It may also has the capabilities of hands free speakerphone, enabling the user to listen to the sound received from the Communicator 118 and talk back from the sound interface 226 through the communication link 114 with the Communicator 118. in such an alternative embodiment of current invention, the HUD Projector unit 100 is also used as a car kit with two way voice capabilities where the communication link 114 connects it to the Communicator 118 that may be such as a cellular phone.

In yet another embodiment of current invention the HUD Projector unit 100 may also comprise GPS receiver 223, which enables receiving GPS signals, process and decode them and use that information for AGPS, or GPS location calculations. The processor 220 may than generate location related information to be presented to displayed on the Display Projector 212. The HUD Projector unit 100 may receive Location Based information from the Communicator 118 through the communication link 114. The Location Based information may be received by the Communicator 118, through the long-range communication 120 from wireless location based services (LBS) such services may be such as navigation and driving directions, jamming avoidance and routing, and other LBS services. The location related information may be store and forward onto the HUD Projector unit 100 according to the GPS information, or be received in real time or pseudo real time, or any combination of store and forward and corrections upon need. It would be appreciate that current invention enables viewing GPS based services such as driving directions, while keeping “eyes on the road” by possibly having GPS capabilities within the HUD 10, which is connected to a Communicator that may not have a built-in GPS.

In yet another embodiment of current invention the HUD Projector unit 100 may also comprise an optical interface 228, which enables receiving visual commands from the vehicle operator. Such as identification of operator activations over virtual keypad that may be projected overlaid via the Visor reflector 232. The optical interface 228 may also sense the light level within the operator FOV. That information is than processed by the HUD Processor unit 200 which than controls the level of radiation of the light source 210

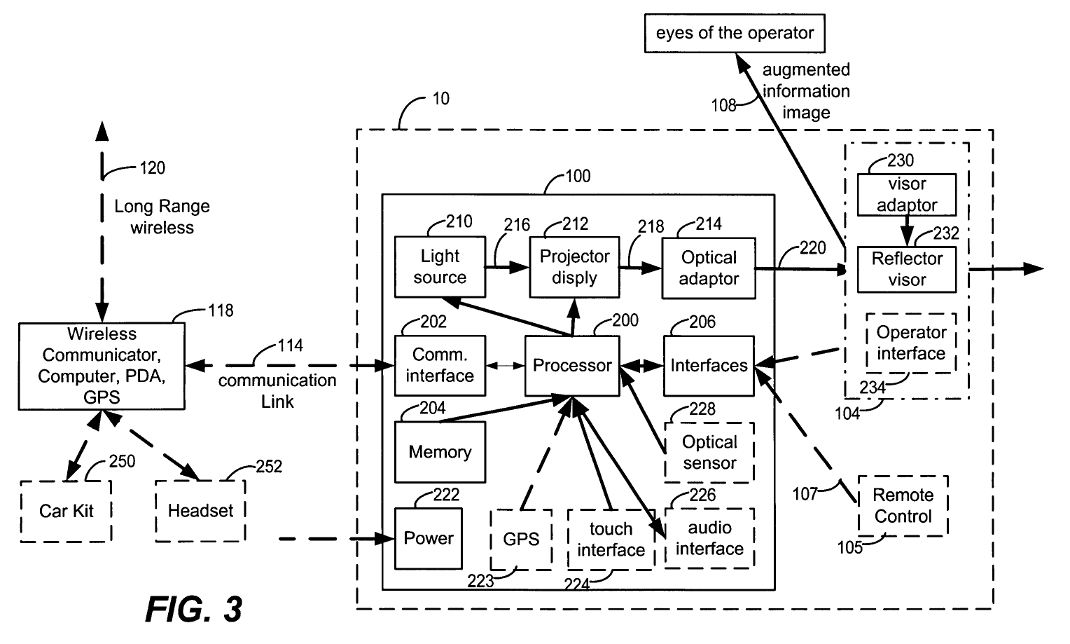

Reference is now made to FIG. 3, which differs from that of FIG. 2 in that whereas FIG. 2 shows a mobile HUD 10 that is connected to a wireless communicator of present invention, FIG. 3 shows implementation combined with a car kit 250 and or a headset 252. A HUD Projector unit 100 may be connected to a central unit 118 such as a cellular phone, which may be also connected to car kit 250. Alternatively, or in addition the Communicator 118 may be connected to a headset. Said connection preferably be RF wireless link, or may alternatively be wired.

FIG. 3 also shows yet another embodiment of the visor unit 104 of current invention. The visor unit 104 may also comprise an operator interface, which enables to operate variety of functionality of the HUD 10, or to operate variety of functionality of the central unit 118. Such preferred functionality of current invention is touch command interface 234, a sound interface, or visual interface. Such a touch command interface may be a transparent touch activation layer that is attached to the reflector visor 232. The operator interface can be located next to the visor adaptor, or in a separate unit, preferably within an easy reach of the operator.

Alternatively, or in addition the Operator can control the functionality of the HUD 10 by using, an easy to reach, remote control 105 with a communication link 107

It would be appreciated that operating a cellular phone, or mobile computer, a GPS unit, or radio, satellite of central unit 118, without taking the eyes of the road would increase driving safety.

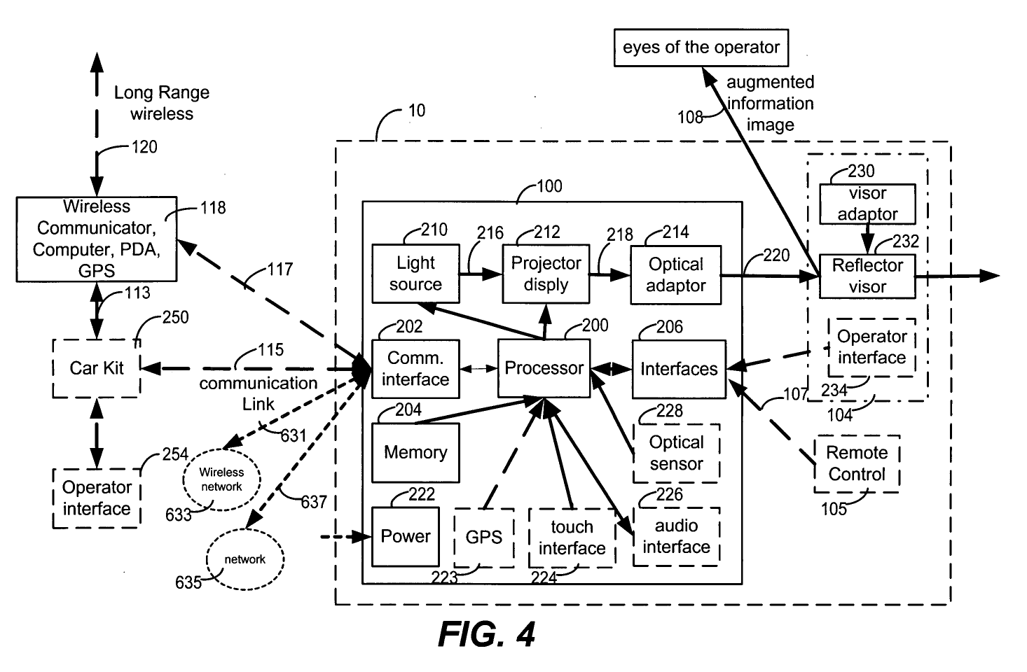

Reference is now made to FIG. 4, which shows a block diagram of yet another embodiment of current invention of Head Up Display (HUD) 10 system showing another possible structure of current invention. A HUD Projector unit 100 may be connected by a car kit 250 with a communication link 115. The car kit 250 may be connected to a Communicator 118 such as a cellular phone via a link 113. car kit 250 may also be connected to another operator interface 254, which may be connected wirelessly to the car kit 250 or directly to the wireless communicator 118. The car kit communication link 115 is preferably be RF wireless link such as Bluetooth, Wi-Fi, Zigbee, NFC, WiMax, or may be wired connection such as a USB, USB2Go, serial link, parallel link, or a proprietary link.

The connection Link 113 between the Communicator 118 to the car kit 250 of current invention would preferably be a RF wireless link such as Bluetooth, Wi-Fi, Zigbee, NFC, UWB, WiMax. Alternatively it may be a wired connection such as a USB, USB2Go, serial link, parallel link, or a proprietary link.

Alternatively, the HUD 100 can be connected directly to the wireless communicator 118 preferably in wireless link 117 such as Bluetooth. At the same time the wireless communicator can also be connected directly to a car kit 250, preferably in wireless link 113 such as Bluetooth, or using a wired link 113.

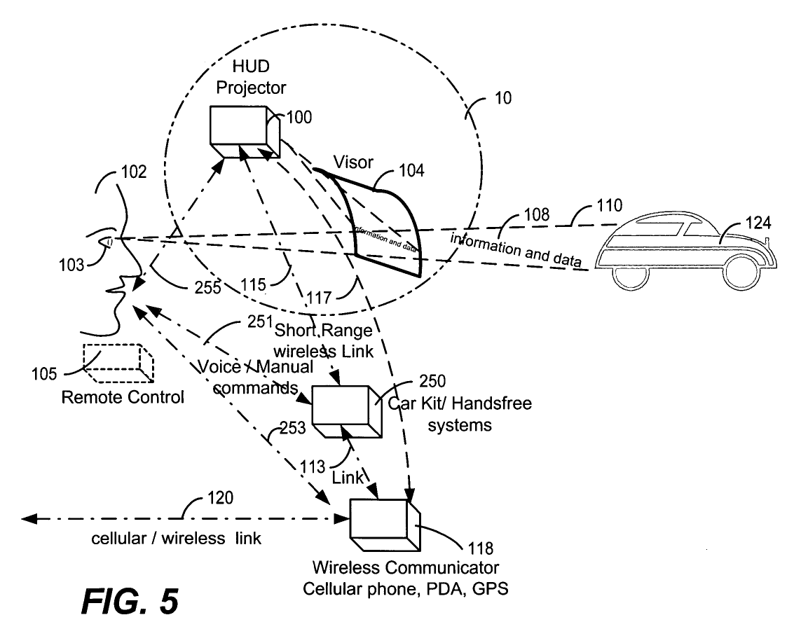

FIG. 5 provides an illustration of yet another embodiment of current invention of Head Up Display (HUD) 10 system for providing augmented information 108 that is projected in front of a vehicle's operator 102.

A long-range communicator device 118 such as a cellular phone, a wireless PDA, wireless computing apparatus, or a GPS, or an infotainment (information-entertainment) system is located within the vehicle cabinet, or embedded in the vehicle. The communicator device 118 is long-range wirelessly connected 120 with a wireless network. Such long-range wireless link 120 of current invention may be cellular network such as GSM, CDMA, GPRS, UMTS, WCDMA, 3G, 4G, or Wi-Fi, WiMax, satellite, GPS, satellite communication and other longer-range RF networks.

Information that is received through a communicator 118, is transferred using a communication link 113 to a Car Kit 250 preferably wirelessly, or wired. The car kit 250 may be used for voice communication such as with central unit 118, which may be a cellular phone. The Car Kit 250 may also be used for transferring information to the HUD projector 100 through a link 115, which preferably a wireless link such as Bluetooth, Wi-Fi, Zigbee, NFC, alternatively it can be implemented over wire such as serial link. Such information may be cellular address book details, SMS, Caller-ID, GPS and other LBS information, and other network based information, or communicator's information. The link 115 may be bi-directional link, which passes information also from the HUD 100 to the communicator 118. Such information may be Operators activations and commands, GPS information (in case a GPS is embedded within the HUD unit 100), or other types of data. Operator 102 commands may be provided by voice, or manual activations. Operator's Commands 253 may be applied directly to the communicator 118. Operator's Commands 251 may be applied through the car kit 250; Operator's Commands 255 may be applied through the HUD 100.

Connection Link 113 of current invention is preferably be wireless link such as Bluetooth, Wi-Fi, Zigbee, NFC, WiMax, or may be wired connection such as a USB, USB2Go, serial link, parallel link, or a proprietary link

The car kit 250 to HUD 10 connection Link 115 of current invention is preferably be wireless link such as Bluetooth, Wi-Fi, Zigbee, NFC, WiMax, or may be wired connection such as a USB, USB2Go, serial link, parallel link, or a proprietary link.

Alternatively, the car kit 250 to HUD projector unit 100 may be connection to the Communicator 118 via a direct link 117. Such a link 117 of current invention is preferably be wireless link such as Bluetooth, Wi-Fi, Zigbee, NFC, WiMax, or may be wired connection such as a USB, USB2Go, serial link, parallel link, or a proprietary link.

A remote Control 105 may be used to control the Operation of the Head Up Display (HUD) projector 100 in such case it would preferably be connected to the HUD projector 100 via a wireless link such as Bluetooth, Wi-Fi, Zigbee, NFC, or proprietary RF. it may also control a car kit 250 directly via a wireless, or a wired link, alternatively it may control directly the communicator 118.

Alternatively or in addition other devices and networks can be connected to the mobile HUD 10. Such a network can be a vehicle wireless network 633 or devices that may be such as Bluetooth, Wi-Fi, Zigbee, NFC, UWB, WiMax, or other wireless networks and devices. The vehicle wireless network 633 can be connected via a link 631 to a communication interface 202. A communication interface 202 may also include wires communication interfaces that possibly are linked 637 to other devices and networks 635 such as CAN serial communications bus.

The information received is than processed within the HUD projector unit 100 and than is projected onto a visor reflector 104. The vehicle operator 102 can than view a superimposing a virtual image 108 within a field-of-view (FOV) on a front view looked through a windshield from an eye point 103 within the vehicle.

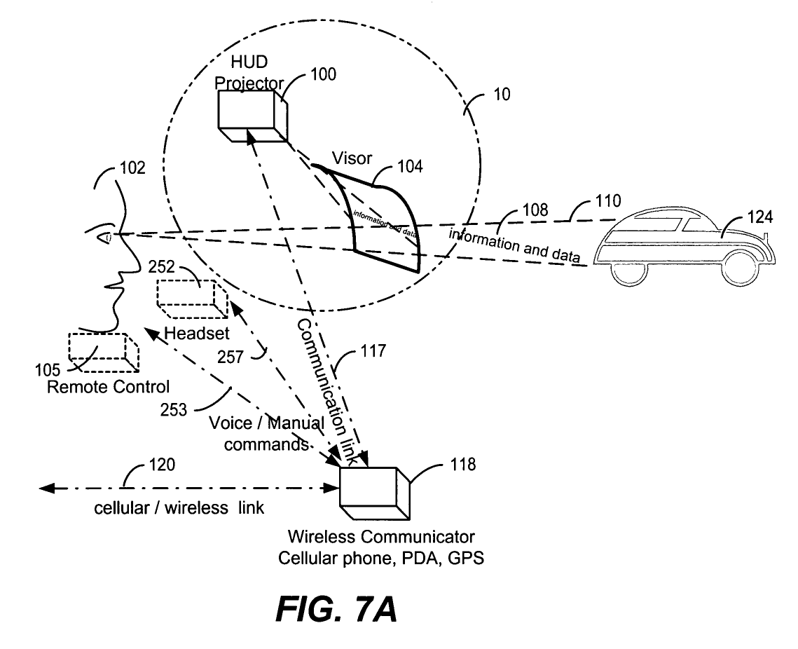

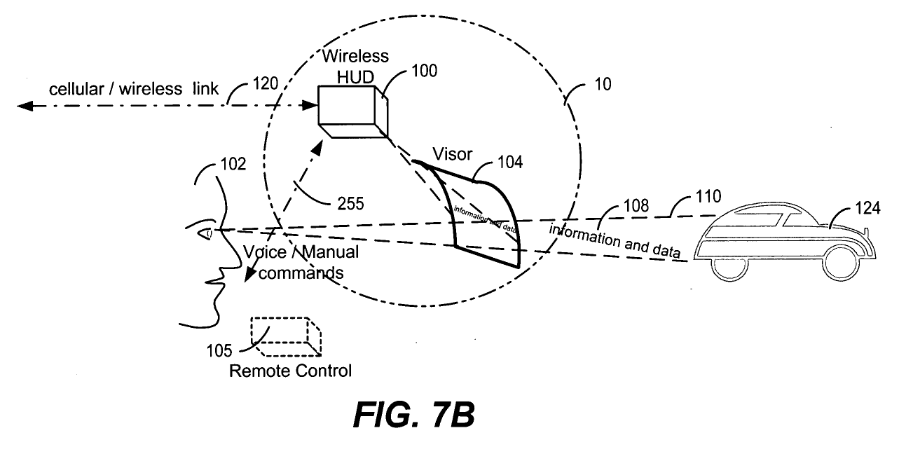

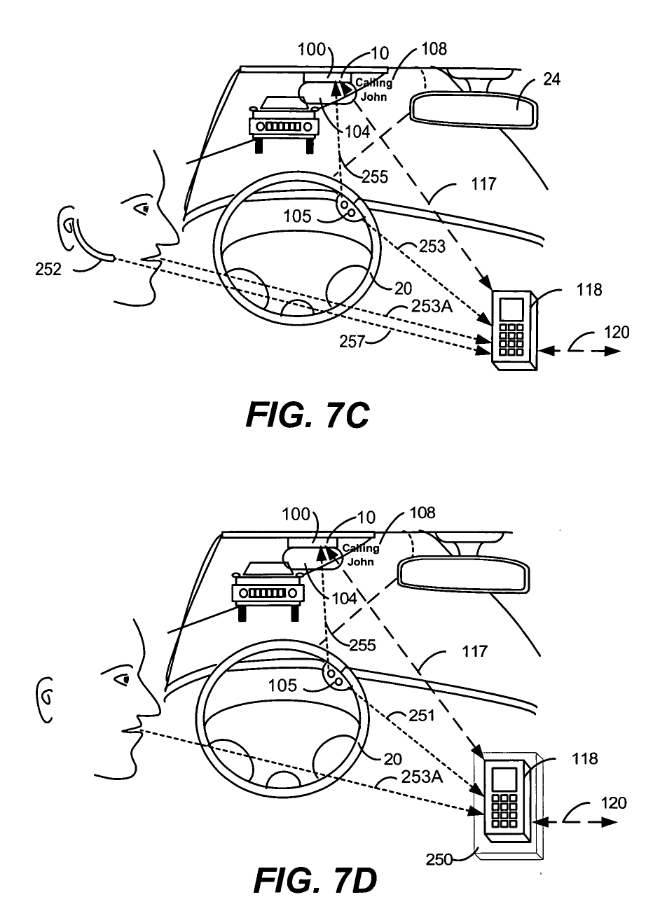

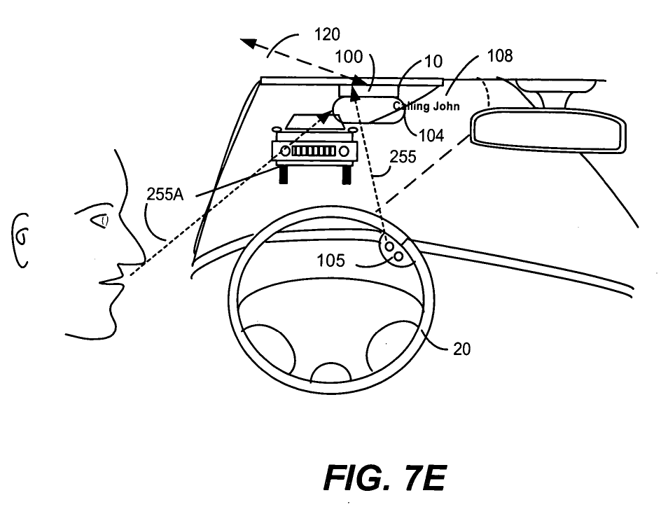

FIG. 7A provides an illustration of yet another embodiment of current invention of Head Up Display (HUD) 10 system for providing augmented information 108 that is projected in front of a vehicle operator 102. A wireless communicator 118 as described in FIG. 5 may preferably be activated with voice activation such as Motorola car phone M800, or M900, or Nokia hand held voice activated cellular phone. Another preferable alternative embodiment of current invention is suing headset 252 that is connected through a link 257 to the communicator 118. Preferably the link 257 is a wireless link such as Bluetooth, or other short-range wireless.

It would be appreciated that the combination of voice activation 253 with a mobile HUD 100 of current invention enables a safer way of using mobile devices while driving and enable the operator 102 to have his eyes on the road and his hands on the driving wheel. This combination for mobile phone application is trade marked as “Hands & Eyes Free™” mobile phone by the inventor.

A remote Control 105 may be used to control the operation of the Communicator 118, and or the Head Up Display (HUD) projector 100 in such case it would preferably be connected via a wireless link such as Bluetooth, Wi-Fi, Zigbee, NFC, or proprietary RF. or a wired link.

Reference is now made to FIG. 7B, which illustrates another preferred embodiment of current invention. A wireless mobile HUD 10, which consists of a long-range wireless link 120 such as a cellular link, WiMax, Wi-Fi, terrestrial and satellite links, proprietary RF link or other links. It would be appreciated that this embodiment of current invention would provide a cost effective HUD solution for displaying remote date and would enable many professional and consumer applications such as driving directions for mobile sells force traffic and weather notices, remote assignments and tasks, etc. one preferred embodiment of a mobile HUD 100 is a mobile HUD 10 that also consist of a mobile phone capabilities in addition of having a head up display capabilities. Preferably the mobile phone with HUD capabilities also has voice command capabilities 225.

Another preferred embodiment is a mobile HUD has GPS capabilities and is connected through a long wireless link 120 to remote information center.

Reference is now made to FIG. 7C, which is a pictorial view of one of the preferred alternatives of current invention that is described in FIG. 5, a mobile HUD 100 is connected near a vehicle windshield (FIG. 7C shows how it can be attached to a sun visor). A mobile communicator 118 communicates (FIG. 7C shows a mobile phone as an example for such communicator). The Mobile HUD 100 communicates with the mobile communicator 118 through a link 117 (FIG. 7C shows a wireless link—preferably Bluetooth or alike); the Mobile HUD 100 can be controlled from a remote control 105 (FIG. 7C shows a remote control that is attached on the steering wheel). The control is done through a link 255 (FIG. 7C shows a wireless link, preferably RF link, alternatively it can also be a wired one). Alternatively the remote control 105 can control the mobile communicator 118 through a link 253 that may be wireless such as Bluetooth, or wired. The information from the mobile communicator 118 is transferred over the link 117 to the mobile HUD 100 processed and is displayed 108 through the visor 104 overlaid with the background images. Alternatively the user may use voice command 253A to command the mobile communicator 118. Yet another alternative that is shown in FIG. 7C is a headset 252 which the user may use to communicate with the mobile communicator 118. this communication may be done through link 257 which is preferably a wireless link such as Bluetooth, or may be done with a wires headset, or a wires microphone.

Reference is now made to FIG. 7D, which is a pictorial view of one of yet another preferred alternatives of current invention that is described in FIG. 5, a mobile HUD 100 is connected near a vehicle windshield (FIG. 7C shows how it can be embedded within the sun visor). A mobile communicator 118 communicates (FIG. 7C shows a mobile phone as an example for such communicator 118). The Mobile HUD 100 communicates with the mobile communicator 118 through a link 117 (FIG. 7C shows a wireless link—preferably Bluetooth or alike). The mobile communicator is connected to a car kit 250. The Mobile HUD 100 can be controlled from a remote control 105 (FIG. 7C shows a remote control that is attached on the steering wheel). The control is done through a link 255 (FIG. 7C shows a wireless link, preferably RF link, alternatively it can also be a wired one). Alternatively the remote control 105 can control the mobile communicator 118, or through the car kit 250, through a link 251 that may be wireless such as Bluetooth, or wired. The information from the mobile communicator is transferred over the link 117 to the mobile HUD 100 processed and is displayed 108 through the visor 104 overlaid with the background images. Alternatively the user may use voice command 253A to command the mobile communicator 118.

Reference is now made to FIG. 7E, which is a pictorial view of one of yet another preferred alternatives of current invention that is described in FIG. 7B, a mobile HUD 100 is connected near a vehicle windshield. The Mobile HUD 100 with long-range wireless capabilities communicates with the wireless network through a wireless link 120. Preferably the wireless communicator is a mobile cellular phone. The Mobile HUD 100 preferably also have voice activation capabilities, so a user may communicate in an audible manner 255A, alternatively or in addition a remote control 105 may communicate with the Mobile HUD 100 over a link 255 which is preferably a wireless link such as Bluetooth, or alike. The Mobile HUD 100 preferably also has GPS capabilities in addition of being a cellular phone. Alternatively it may be a wireless GPS that can be updated remotely.

The information from the mobile communicator is transferred over the link 117 to the mobile HUD 100 processed and is displayed 108 through the visor 104 overlaid with the background images.

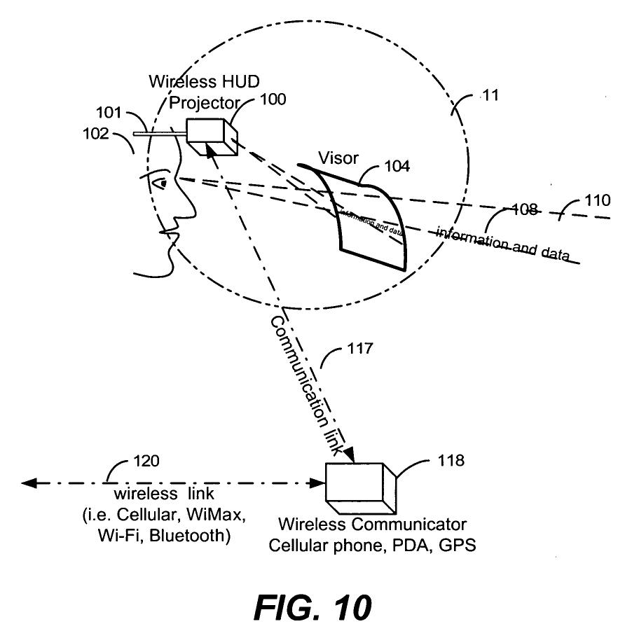

Reference is now made to FIG. 10. FIG. 10 provides an illustration of yet another embodiment of current invention of a wearable Head Up Display (HUD) 11 system for providing augmented information 108 that is projected in front of user 102. It would be appreciated that Head Up Display (HUD) 11 of current invention is a wireless wearable HUD which enables displaying augmented information 108 on the move. Having a wireless wearable HUD frees the user from wiring that limits his movements.

A user wears A wireless wearable HUD Projector 100 using a HUD fastener 101. A long-range communicator device 118 such as a cellular phone, a wireless PDA, an infotainment (information-entertainment) system, wireless computing apparatus, or a GPS is carried by the user, or is located closed by. The communicator device 118 is medium, or long-range wirelessly connected 120 with a wireless network. Such long-range wireless connection 120 of current invention may be cellular network such as GSM, CDMA, GPRS, UMTS, WCDMA, 3G, 4G, or local wireless networks such as Wi-Fi, UWB, NFC, WiMax, or satellite, GPS, and other longer-range RF networks.

Information, which the user 102 needs, is wirelessly transferred from the communicator device 118 using a communication link 117 to a wearable wireless HUD 100.

The Connection Link 117 of current invention is preferably be RF wireless link such as Bluetooth, Wi-Fi, Zigbee, WiMax, UWB, NFC, or may be wired connection such as a USB, USB2Go, serial link, parallel link, or a proprietary link.

The wireless wearable HUD Projector 100 may also have built in GPS and or a compass, and or one or more axis gyros for location and angular orientation.

The information received is than processed within the HUD projector unit 100 and than is projected onto a visor reflector 104. The user 102 can than view a superimposing a virtual image 108 within a field-of-view (FOV) on a front view looked through visor from an eye point.

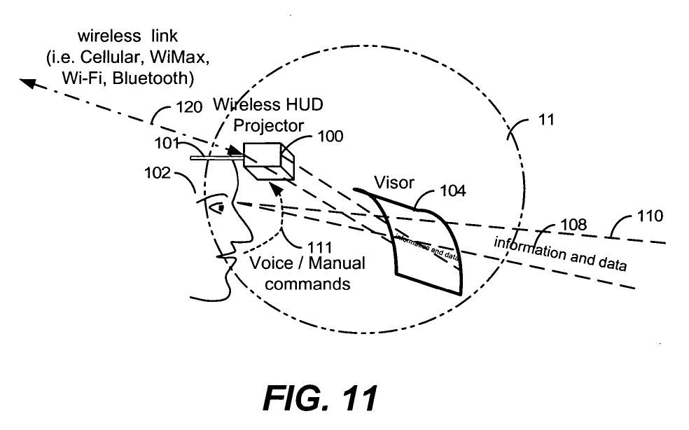

FIG. 11 provides an illustration of yet another embodiment of current invention of a wearable Head Up Display (HUD) 11 system for providing augmented information 108 that is projected in front of user 102. It would be appreciated that Head Up Display (HUD) 11 of current invention is a wearable wireless HUD that enables displaying augmented information 108 on the move without carrying any computing device. Having a wireless wearable HUD 11 also frees the user from wiring that limits his movements.

The integrated medium/long range wireless communication enables the user to access remote information and display it as an overlay of the images he sees in front of him. As a result the a wireless wearable HUD 11 enables a technician, or an engineer user to access remote maintenance and manuals information, a medical user may access remote medical information and or operation plans and other relevant information to what he needs while free his hands for other deeds.

A user wears A wireless wearable HUD Projector 100 using a HUD fastener 101. The wireless wearable HUD Projector 100 also consists of a medium, or long-range wireless communicating means which enables wireless connectivity to a remote computer, or a remote network. Such communicating means may be a cellular modem, a wireless local area network modem, or a metropolitan wireless network modem.

Such long-range wireless connection 120 of current invention may be cellular network such as GSM, CDMA, GPRS, UMTS, WCDMA, 3G, 4G, or local wireless networks such as Wi-Fi, WiMax, NFC, UWB, or satellite, GPS, and other longer-range RF networks.

The wireless wearable HUD Projector 100 may also have built in GPS and or a compass, and or one or more axis gyros for location and angular orientation.

Information, which the user 102 needs, is wirelessly transferred from the remote computing device, or remote network using a communication link 120 to a wearable wireless HUD 100.

The information received is than processed within the HUD projector unit 100 and than is projected onto a visor reflector 104. The user 102 can than view a superimposing a virtual image 108 within a field-of-view (FOV) on a front view looked through visor from an eye point.

User may interact, or command the HUD, the remote computer, or remote network by voice commands, or by manual command 111 which are received by the HUD projector unit 100

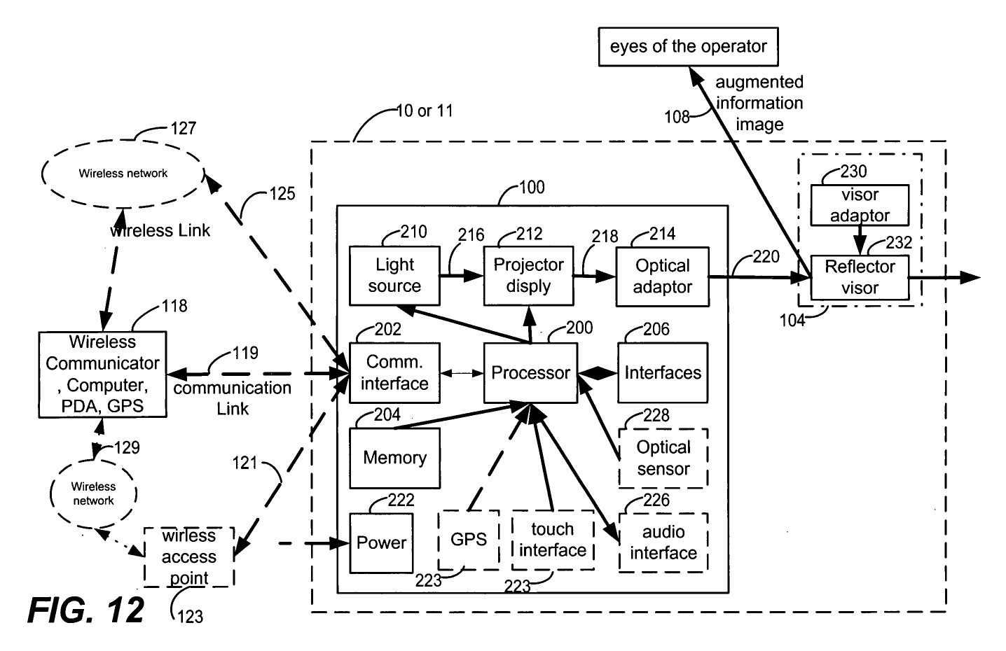

Reference is now made to FIG. 12. FIG. 12 is a block diagram of yet another embodiment of current invention of Wireless Head Up Display (HUD) 10, or a wearable Wireless Head Up Display (HUD) 11 system showing another possible structure of current invention. A HUD Projector unit 100 may be connected to a portable computing, or communication apparatus 118, using a RF wireless link 119 such as Wi-Fi, Bluetooth, Zigbee, NFC, UWB, WiMax, or other short-range or medium-range wireless. Alternatively or in addition it can be wirelessly connected through a wireless link 125, to a wireless network 127 such as GSM, CDMA, DVB, GPRS, EDGE, WCDMA 3G, 4G, or other long range or cellular wireless networks. Alternatively or in addition it can be wirelessly connected through a wireless link 121, to a wireless network 129 through a wireless access point 123, or directly.

It would be appreciated that current embodiment of present invention would free the user from carrying any additional communication, or computing apparatus and the HUD 10/11 would become a wearable display and interaction apparatus enable him to use it hands free.

A portable computing, or communication apparatus 118 may be connected to Wireless Local Area Network 129, or long range/cellular wireless network 127.

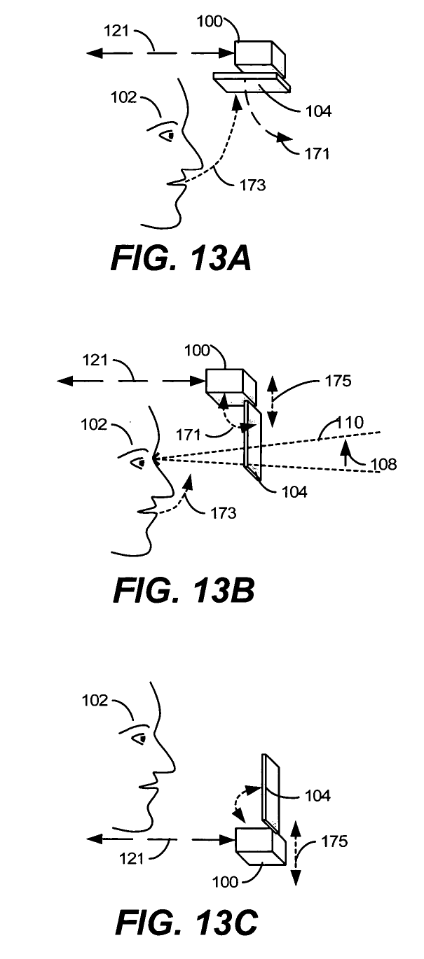

Reference is now made to FIG. 13A, 13B 13C, providing illustrations of yet another embodiments of current invention of wireless Head Up Display (HUD) 100 system for providing augmented information that is projected in front of a vehicle operator 102.

Referring now to FIGS. 13A and 13B, A HUD projector unit 100 consists of communication means for receiving information to be displayed to an operator of a vehicle, An image is generated within a HUD projector 100, the image is than projected onto a visor reflector 104. The user 102 can than view a superimposing a virtual image 108 within a field-of-view (FOV) 110 on a front view looked through a windshield from an eye point within the vehicle.

While not using the HUD, the visor reflector 104 may be in an inactive position such as described in FIG. 13A. On demand, the visor reflector 104 may be placed into an active position such as described in FIG. 13B.

Putting the visor reflector 104 into an active position may be initiated by the user using voice command, or manual activation, or by the Head Up Display (HUD) projector unit 100. That may be driven by internal cause, or by an external event or request, such external event may be receiving a cellular call, activation of the cellular phone, searching the address book within the cellular phone, activation of a GPS, or a computing apparatus.

A visor reflector 104 may be put in an inactive position using voice command, or manual command, such as a press of a button, or by the Head Up Display (HUD) projector unit 100, that can be driven by an internal event, or by external event, or a request, such external event may be termination of a cellular call, time of not being used. Identifying an emergency situation will automatically place the visor reflector 104 in its inactive position.

A visor reflector 104 may be detachable, so while a severe situation occur, which may put the user in danger, such as vehicle accident, the visor reflector 104 may be decoupled from the its adaptor.

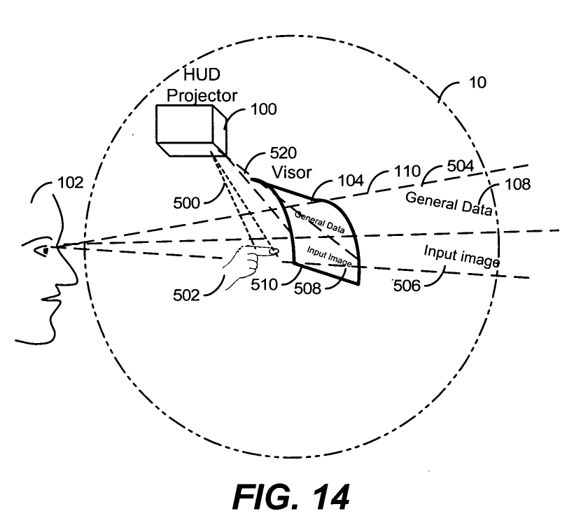

FIG. 14C shows a pop in and out version 175 of current invention that can be attached on the bottom side of the window windshield or on its upper side.

Preferably within a vehicle, a HUD projector 100 may be attached to, or built into a dashboard, a sun visor, or a back mirror. Alternatively it may be attached to the windshield, or the vehicles chassis.

Reference is now made to FIG. 14, which illustrates a data input method and system of HUD 10, which is operative and constructed in accordance with a yet another preferred embodiment of the present invention. Data input device preferably includes a projector 100 which projects an image 520 onto a HUD visor's reflector 104 the projected image is viewed by the user 102 as is appears in a distance away 108. The projected image within the user's 102 Field Of View (FOV) of a HUD 108 may include two or more parts of images. One part may include an image of information and data 504 such as cell phone, or computing apparatuses information, or GPS related information. Another image part may include an input related image 506, such as images of buttons. Images of the input means may be used as virtual buttons for entering data to the HUD.

One preferred embodiment of present invention is a image sensor such as a CCD image sensor scans 500 the data entry portion of HUD's visor 508. The visual sensor may be located within the HUD unit 100 scanning the HUD visor's reflector 104 surface. A user may “activate” the data input means by approaching his finger 502 to the virtual button image of the HUD's visor 510. The HUD's visual sensor passes these images to the HUD processor, which processes the presence of the finger next to the HUD's visor and its location. The processor than makes a decision of what button was activated. Once an activation of input means are identified, that data may be used for controlling the HUD operation and or for passing that data to a remote computing, or communicating apparatus. Such virtual data input means may be virtual keys for controlling a cellular phone, portable computer, a GPS, infotainment, or other apparatuses, which are connected to the HUD.

Additionally or alternatively the HUD input device of present invention may consist of touch screen. Preferably the touch screen will be a transparent touch screen. It may also be functional touch screen that its functionality may be control by software. Alternatively the input device may be capacitance, or inductive input means, acoustical presence and location means, or magnetic means that are attached or part of the HUD's visor 104. A HUD System 10 with such input means may be wirelessly connected to a wireless communication apparatus, connected to a communication apparatus, GPS apparatus, or a computing device.

Additionally or alternatively the HUD input device keys may be located around or on the HUD visor reflector 104 for convenient use in case simple keys would be used.

A HUD System 10 with such input means may be installed within vehicles such as cars, airplanes, boats, and trains. Alternatively it can be used as a wearable HUD.

Such data entry keys may be wireless using RF technologies such as Bluetooth, Zigbee, NFC, or other short-range wireless.

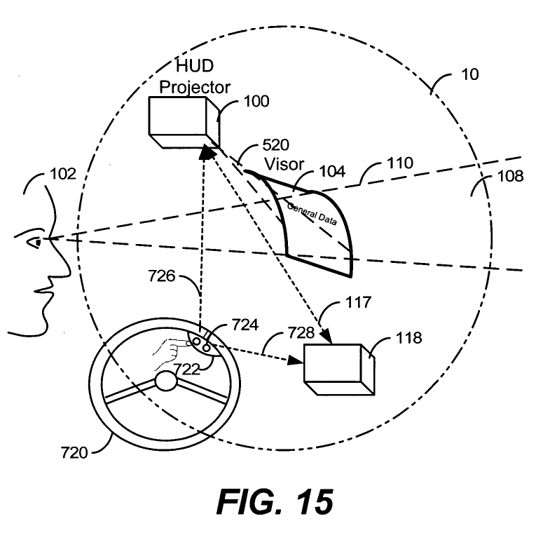

Reference is now made to FIG. 15, which illustrates a data input method and system of HUD 10, which is operative and constructed in accordance with a yet another preferred embodiment of the present invention. A keypad 722 that is located near the vehicles operator's hands, preferably on the steering device 720 and is linked to the HUD projector 100 through link 726, or and to the communication/computing/GPS apparatus 118 through link 728. Preferably the input keypad 722, such as described by 105 of FIG. 5. would use wireless communication for link 726, and or link 728. The wireless link may be RF link such as Bluetooth, Zigbee, NFC, or other proprietary links such as RFWaves, Chipcon.

The input keypad 722 may be attached next to the driver and within a simple reach of the operator, or attached to the steering wheel 720, be or be built in the steering wheel 720. By pressing keys 724 user may remotely operate the communication/computing/GPS apparatus 118, or the HUD operation itself. It would be appreciated that wireless keypad 722 of preferred embodiment of the present invention would enable vehicle operator to search through the address book of his cellular phone while pressing buttons 724 without taking the hands off the wheel and while looking at the phone numbers overlaid with the traffic in front of the car and without taking his eyes off the road.

The wireless input keypad 722 may be connected directly 728 to the cell phone, or GPS, or infotainment, or mobile computer 118, or through the wireless link 726 of the HUD projector 100.

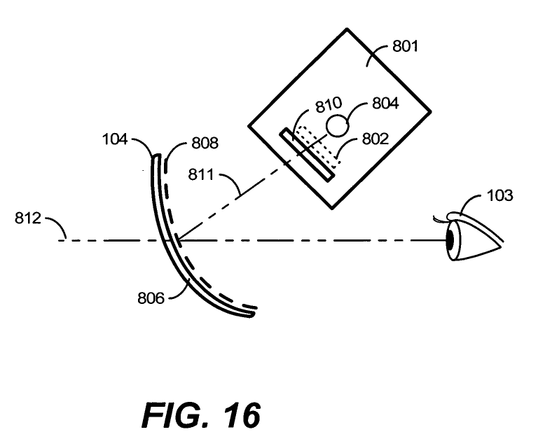

Reference is now made to FIG. 16, which illustrates a monochromatic HUD projector 801, which is operative and constructed in accordance with a preferred embodiment of the present invention. An image is created at the LCD 810. A light, preferably at a color of the monochromatic HUD color, or a white light, is generated by a light source 804. Such a light source can be LED with an adequate color. The light is projected via a diffuser 802, than through a LCD 810. The LCD 810 is operating in the transitive mode. The LCD 810 functions as shutter in various shape and color. A light that is emitted 811 from the LCD 810 is reflected by the visor/lens/mirror 104 to the eye of the observer 103. The image seen by the observer is magnified according to the visor optical gain and is placed virtually in front of the field of view and at distance 812, which can be controlled by the distance to the image source or by the focal length of the visor. A lens 806 is coated by an optical coating 808 and is selectively reflective in the color, which the image is generated at the source LCD in it is transparent in other colors.

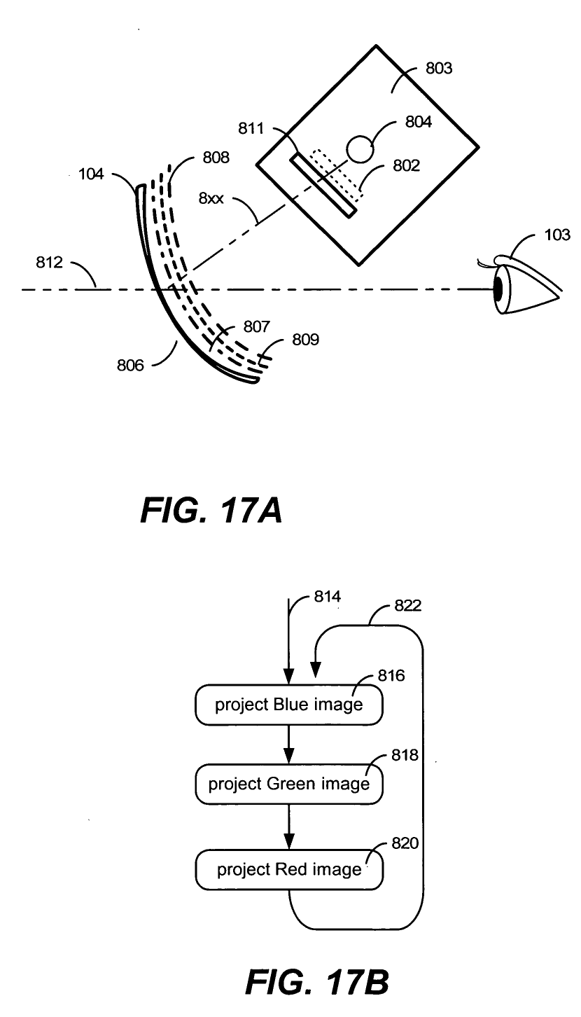

Reference is now made to FIG. 17A, which illustrates a multi-color HUD 803, which is operative and constructed in accordance with a yet another preferred embodiment of the present invention. Image is created at the LCD 811. A light, preferably a white light, is generated by a light source 804. Such a light source can be LED. The light is projected via a diffuser 802, then through the LCD 811. The LCD 811 is operating in the transitive mode. The LCD 811 functions as shutter in various shape and color. The light emitted from the LCD 811, is reflected by the visor/lens/mirror 104 to the eye of the observer 103. The image seen by the observer is magnified and is placed virtually in front of the field of view and at distance, which can be controlled by the distance to the image source or by the focal length of the visor. The coating 807, 808, 809 on the lens 806 is selectively reflective in the different colors. Then different colors images are then generated on the color LCD 811 in a Time Division Multiplexing (TDM) and projected onto the visor 806 the relevant coating layer reflects the relevant image the observer eyes 103 then integrate the TDM images and creates a complete color image.

Reference is now made to FIG. 17B, which shows one possible flow diagram of a multi-color HUD 803 as described in FIG. 17A, which is operative and constructed in accordance with a yet another preferred embodiment of the present invention. Images in different colors such as Blue Green and red are generated at the color LCD 811 of FIG. 17A. They are created in a Time Division Multiplexing (TDM), The process may start 814 by generating the first color image 816, such as a Blue image, and then another color image is generated 818, such as a Green image and then another color image is generated 820 such as a Red image. Then the process repeats 822 with the first color. Tow or basic colors may be used. A full color Frame is accomplished by a projecting all the basic colors images. The color LCD resolution, size and quality, frame rate and LED illumination determines the image quality of the color HUD 803.

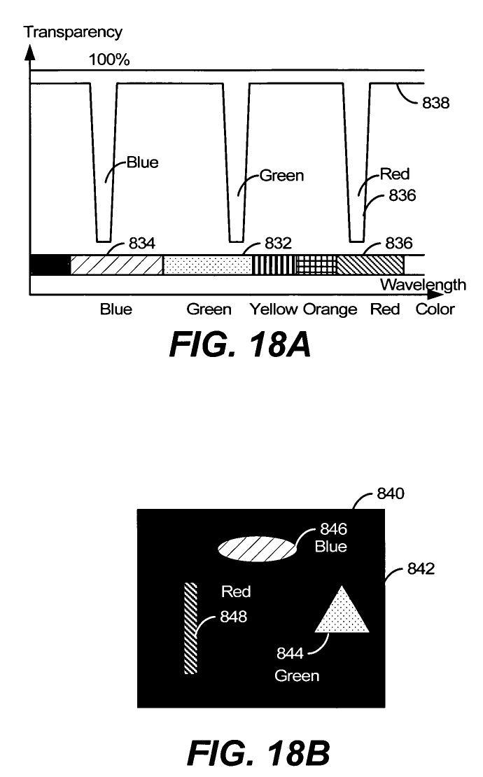

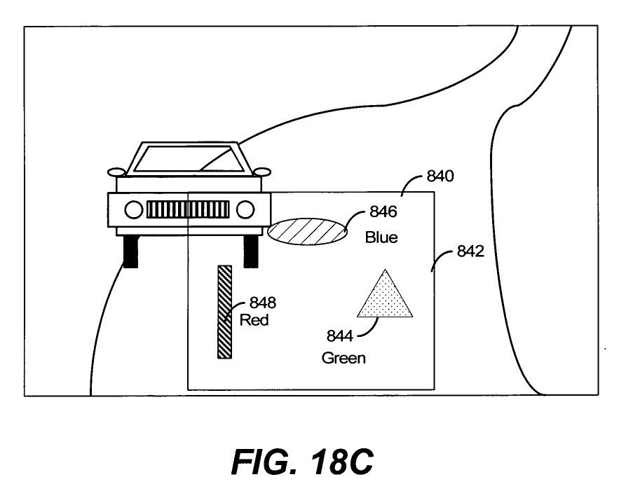

Reference is now made to FIGS. 18A, 18B, 18C which illustrates a multi-color HUD, which is operative and constructed in accordance with a yet another preferred embodiment of the present invention. A visor/lens is coated with a partial transparency and partially reflective coating. Several regions (three regions are shown in FIG. 18A as an example) of the red 830, green 832, and blue 834, a low transparency (hi reflection) of light 836 will be implemented and at all other regions (wave lengths) there is a high transparency of corresponding light 838. The over all transfer function of the lens is of a mirror or at the red, blue and green and as a transparent at other wavelengths (this is from the image in the field of view).

Reference is now made to FIG. 18B, which illustrates an image of the color LCD 840 where the dark blocks 842 all the white light from the light source. The various areas are transparent to specific colors, for example the rectangular figure of the LCD 848 is transparent to all colors but red. As a result any image within that rectangular area of the LCD will be viewed by the user in red while the LCD is projected in white or red lights. Similarly the figure “8” in the LCD 844 is transparent to all colors but green. The images of interest are in the colors, which the visor reflects.

Reference is now made to FIG. 18C, which illustrates a sample image of an augmented image 840 where various colors images from the LCD, are seen by the viewer. The specific images are reflected as they are in the same wavelength as the notches in the mirror/lens transfer function. The optics of the a-spherical lens/visor/mirror has an additional purpose of enlargement and placing the virtual image at a predefined distance such as infinity which suites a car or a pilot operator.

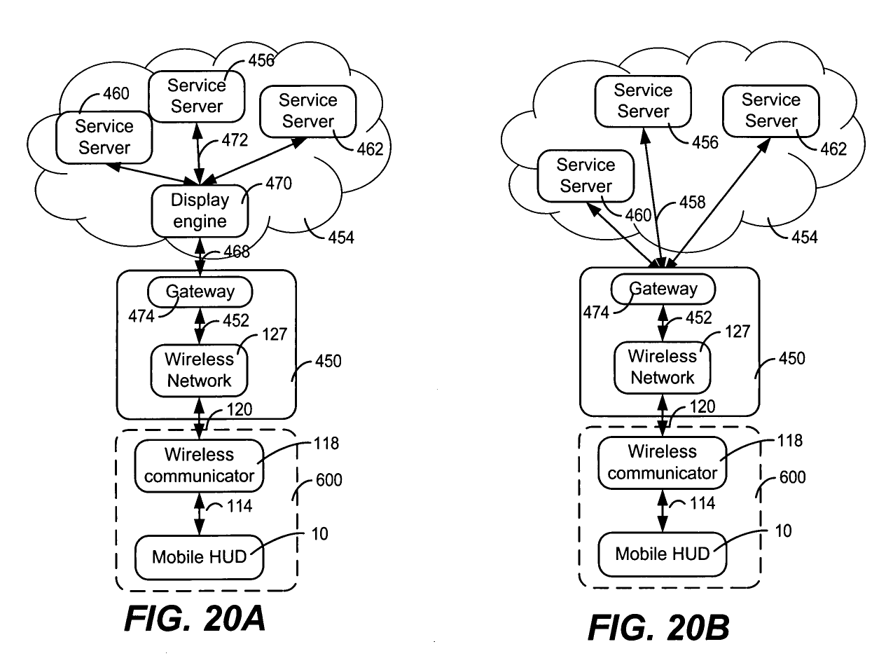

Reference is now made to FIGS. 20A and 20B, which are simplified partially pictorial functional block diagram illustrating a preferred embodiment of the present invention, including displaying of information that is received from a wireless network 117 and is preferably displayed by a mobile HUD 10 in accordance with a yet another preferred embodiment of the present invention.

It would be appreciated that current invention enables displaying WEB and other networks based information to operators of vehicles on the go and while enabling them to keep their eyes on the road. A mobile HUD 10 is connected to a mobile wireless communicator 118 such as a mobile phone. Alternatively a mobile wireless communicator with a built in HUD 600 can be used. The wireless mobile communicator 118 is connected to the wireless network 117 via a wireless link 120. The wireless network 117 is also connected with a Wireless-to-WEB gateway 474 within the wireless service provider (Operator) 450. Referring now to FIG. 20A, the Gateway 474 is connected to a Display Engine 470 that is located on the WEB and is connected 472 through the WEB to services Service Servers such 456, 460 and 462. These service Servers 456, 460 and 462 provide services such as LBS (Location based services). The Display Engine 470 processes their Information before being sent back through the wireless network operator 450 and the wireless communicator 118 to be displayed on the mobile HUD 10. FIG. 20B is another preferred implementation of current invention and where the service Servers such 456, 460 and 462 are connected directly to the operator 450 and the display processing of fitting the information formats to formats that that are adequate for being displayed on the Mobile HUD 10 are performed within the service Servers such 456, 460 and 462 services. Another preferred alterative of current invention (with is not shown) is that the formats conversion of the information received from the service Servers such 456, 460 and 462 will be performed within the wireless service provider (Operator) 450 premises.

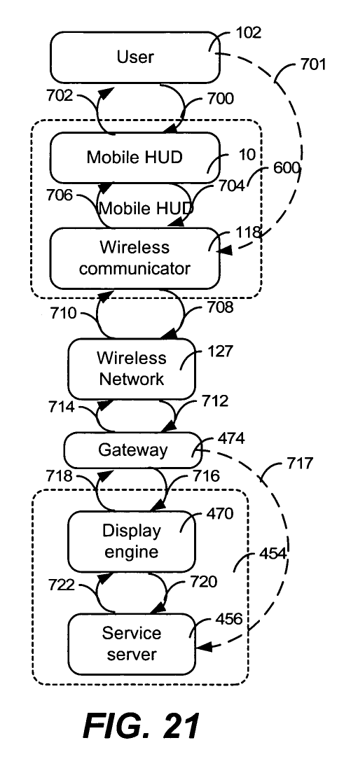

Reference is now made to FIG. 21, which shows a simplified flow diagrams of a process of displaying information from wireless network 117 onto a wireless mobile HUD 10 in accordance with a yet another preferred embodiment of the present invention. A user 102 may initiate a process of retrieving and display remote information from a service Server 456. The user 102 may submit a command 700 to the mobile HUD 10. Alternatively user 102 may submit a command directly to the wireless communicator 118. User may also register to specific services and upon certain conditions that system will automatically initiate the information deliver process without direct command by a user 102. In case where the command is submitted to the mobile HUD 10, the mobile HUD relays the request 704 to the wireless communicator 118. As shown in FIG. 21, the HUD 10, and the wireless communicator 118 may be implemented as separate unites, or be embedded within one unit, which is a mobile communicator with a built in HUD 600. Wireless communicator 118 wirelessly communicates the request 706 to the wireless network 127. Through a gateway 474 to the Internet, the request is passed 716 via a Display engine 470 and through communication 720 to a service Server 456 of the requested information service. Alternative routing of the request may be applied such as a direct request 717 from the gateway 474 to the service Server 456. The requested information is then provided by the service Server 456 through 722 to the display engine 470. The display engine then processes that information and optimizes it for the Mobile HUD display 10. It will typically perform format conversion, filtering, resizing and other possible processes. The reformatted information is passed 718 through the gateway 474 and via 714 to the wireless network 127. The wireless network 127 communicates 710 the information through the mobile communicator 118 and through the link 706 to the mobile HUD 10. The information is then presented 702 to the user 102. It would be appreciated that according to current invention user 102 may interact with the information using vocal commands as described in FIG. 5, or manual commands such as using a remote control.

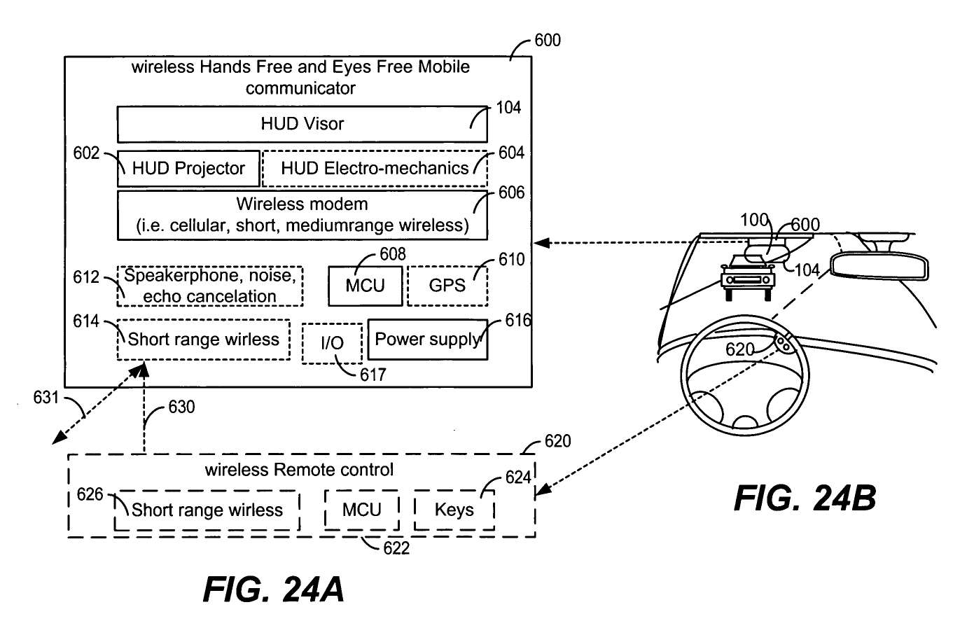

Reference is now made to FIGS. 24A, and 24B which are a block diagram of a mobile phone with built in mobile HUD 600 and a pictorial view of a mobile phone with built in mobile HUD 600 respectively in accordance with a yet another preferred embodiment of the present invention. A mobile phone with built in mobile HUD 600 consists of a HUD projector 602 that projects images that are generated by MCU 608. A HUD visor 104 for displaying the projected images. It may also consist of HUD electro-mechanics 604 for possible mechanical operations of the HUD such as moving the visor in active position, or to its inactive position. A long-range wireless modem 606 communicates with long-range wireless networks such as cellular network, Wi-Fi, WiMax, or other long-range wireless networks. A processor MCU 608 manages the activities of mobile phone with built in mobile HUD 600. it also may include a speakerphone capabilities as well as noise and echo cancellation 612 implemented in software or hardware. It may also include GPS receiver 610 supporting either AGPS, or GPS capabilities. It also includes a power supply 616 that may also consist of rechargeable batteries, external supply and optional solar power supply. It may include also I/O functions 617 such as keys, and or communication line such as serial links. The mobile phone with built in mobile HUD 600 may also include one or more short-range wireless modems 614 such as Bluetooth, 802.15.4 Zigbee, or others. These short-range wireless links may be use for communicating 630 with a remote control 620 or communicate 630 with other devices such as wireless headset, a Bluetooth device. A Bluetooth interface to the vehicle's network and others.

A remote control 620 may communicate with the mobile phone with built in mobile HUD 600 over wireless or wired link 630. It typically has a processor MCU or ASIC 622 to manage its operation and keys 624.

Referring now to FIG. 24B, which is a pictorial view of one possible implementation of a mobile phone with built in mobile HUD 600 that may be attached on the dashboard, or be embedded or attached in other locations within a vehicle and a possible remote control 620.

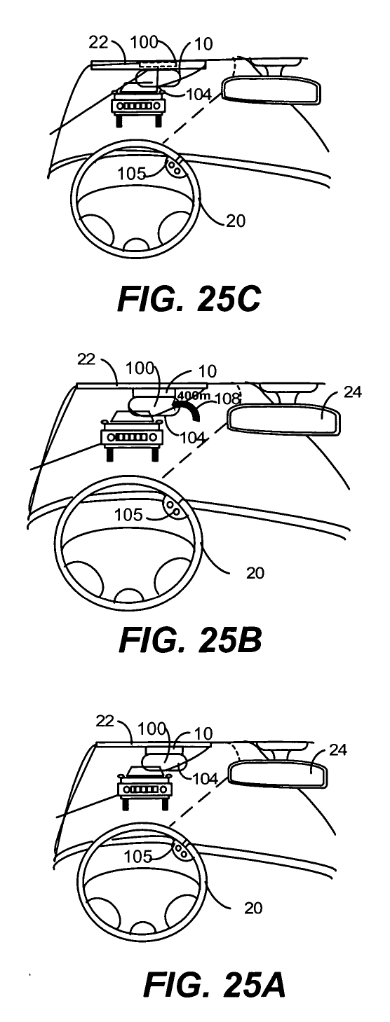

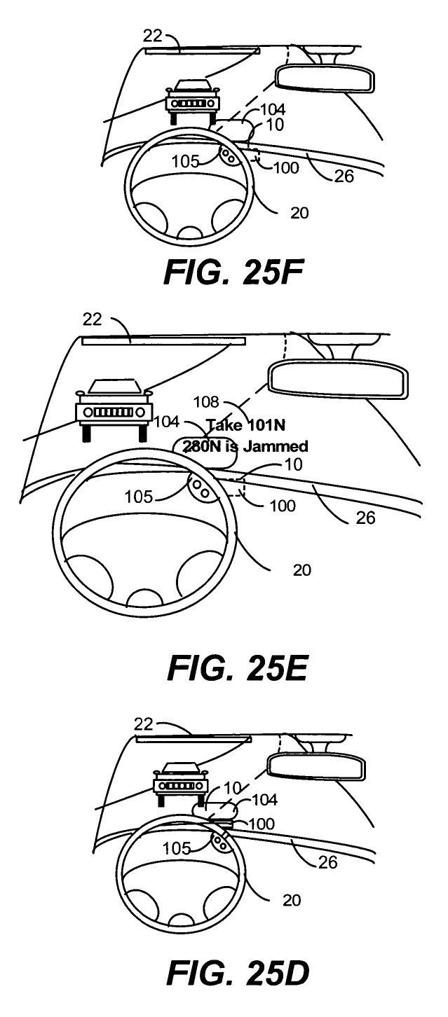

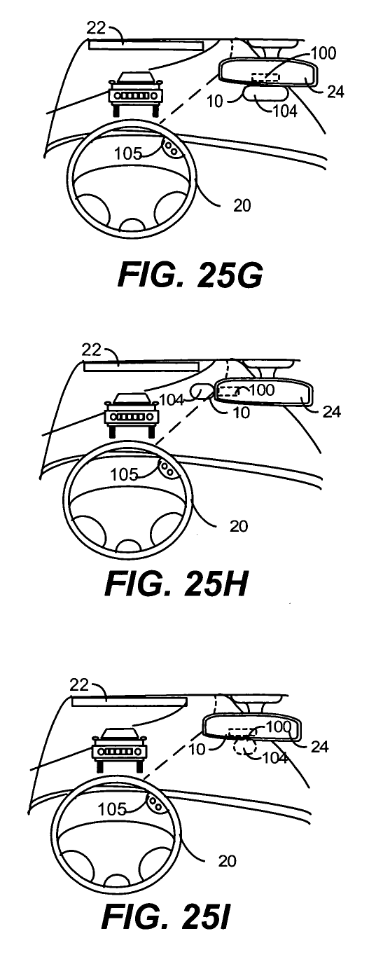

Reference is now made to FIGS. 25A, B, C, D, E, F, G, H which are pictorial views and illustrates of some preferred implementations of a mobile HUD 10 or a mobile phone with a built in HUD 600 (for convenience the markings in the Figs are of 10 only) within a vehicle in accordance with a yet another preferred embodiment of the present invention.

FIG. 25A provides an illustration of yet another embodiment of current invention of mobile HUD 10 system where the mobile HUD projector unit 100 is located in the upper end of the vehicle windshield, preferably attached to the vehicle's sun visor 22. A remote control 105 may be connected to the steering wheel 20. In all FIG. 25 visor 104 may have active position and inactive position and mobile HUD 10 may move the visor 104 between these positions as explained in FIG. 13 A, B, C

In all FIG. 25 visor 104 is preferably part of the mobile HUD 10, alternatively it may be attached to the windshield such as an optical foil, or is part if the windshield structure.

FIG. 25B provides a pictorial view of the mobile HUD 10 system as described in FIG. 25A. It also shows an example image of a direction arrow 108 that is projected by the mobile HUD projector 100 onto the visor 104. The image is overlaid on the background image and within the driver's field of view. FIG. 25C provides an illustration of yet another embodiment of current invention of mobile HUD 10 system where the mobile HUD projector unit 10 is located within the vehicle's sun visor 22. It would be appreciated that current invention would enable a vehicle's OEM to produce vehicles with built in mobile HUDs 10.

FIG. 25D provides an illustration of yet another embodiment of current invention of mobile HUD 10 system where the mobile HUD projector unit 100 is located in the lower end of the vehicle windshield, preferably attached to the vehicle's dashboard 26.

FIG. 25E provides a pictorial view of the mobile HUD 10 system as described in FIG. 25D. It also shows an example image of cellular call information 108 that is projected by the mobile HUD projector 100 onto the visor 104.

FIG. 25F provides an illustration of yet another embodiment of current invention of mobile HUD 10 system where the mobile HUD projector unit 10 is located within the vehicle's dashboard 26. It would be appreciated that current invention would enable a vehicle's OEM to produce vehicles with built in mobile HUDs 10 with the vehicle's dashboard 26.

FIG. 25G provides an illustration of yet another embodiment of current invention of mobile HUD 10 system where the mobile HUD projector unit 100 is located near the vehicle back mirror 24, preferably attached to the vehicle's back mirror 24, alternatively it be part of the back mirror 24. FIG. 25G provides an illustration of the mobile HUD unit 10 where the visor 104 is located on the lower end of the back mirror 24.

FIG. 25G provides an illustration of the mobile HUD unit 10 where the visor 104 is located on the side end of the back mirror 24

FIG. 25H provides an illustration of the mobile HUD unit 10 where the visor 104 is located within the back mirror 24

It is appreciated that the mobile head up display (HUD) embodiments of the present invention are typically capable of enabling a user to view and possibly interact with mobile information while in a safer manner than today's solutions. Using present invention, a user may dial, receive a call, or watch cellular information such as SMS while keeping his eyes on the road and his hands on the steering wheel.

It is further appreciated that network based information services can be consumed by a user of present invention with reduced risks. Such services are navigation and routing information, and other location based services.

It is further appreciated that user of present invention would be able operate and view these and other services, applications and apparatuses such as infotainment systems. User may interact with said local and remote information service using voice commands, or using remote controls, enabling keeping his hands on the wheel

It is further appreciated that present invention technology enables significantly reducing costs of HUDs and therefore make it affordable to users thus increasing the driving safety while using cellular phones and other mobile apparatuses such as GPS.

Additionally, according to pre-determined criteria or specific requirement of a user information can be projected to the user of present invention without the need to operate it.

It is further appreciated that present invention enables using the invention embodiment as an add-on in any car without the need to have a special windshield and without the need to have a special dashboard.

It is further appreciated that present invention enables a user to read the projected information without changing his eyes focus to a different distance since the image is perceived to be in a distance ahead of his eyes.

It is further appreciated that present invention enables a user to seamlessly connect his cellular and mobile phone and other mobile device in a very simple manner using wireless communication that is available within his devices to the mobile HUD.

It is further appreciated that present invention enables a user to connect his mobile HUD to other information sources such as situation awareness, infotainment systems and vehicle systems using a wireless or other standard communications

It will be appreciated by persons skilled in the art that the present invention is not limited by what has been particularly shown and described hereinabove. Rather the scope of the present invention includes both combinations and sub combinations of the various features described hereinabove as well as variations and modifications which would occur to persons skilled in the art upon reading the specification and which are not in the prior art.

1. In a mobile communications environment including a mobile communicator in communication with a wireless communication network, a mobile display system comprising:
a Head Up Display apparatus operative to display augmented information within field of view of the eyes the vehicle operator;
a link between said mobile communicator and said Head Up Display apparatus;
Wireless inputs means operative by said vehicle operator operative to control said mobile communicator; and
wherein said Head Up Display apparatus is being capable of displaying information of said mobile communicator; and
at least said mobile communicator is capable of retrieving remote information from said wireless network and pass it to said Head Up Display apparatus.

2. A mobile display system according to claim 1 and wherein said mobile communicator is a cellular apparatus.

3. A mobile display system according to claim 1 and wherein said link between said mobile communicator and said Head Up Display apparatus is wireless

4. A mobile display system according to claim 3 and wherein said link between said mobile communicator and said Head Up Display apparatus is at least one of the following wireless technologies: Bluetooth, Wi-Fi, WiMax, UWB, NFC, ZigBee, 802.15.4

5. A mobile display system according to claim 1 and wherein said mobile communicator information may be of the at least one of the following types: Caller ID, phone number, address book numbers or names; SMS, MMS, emails, maps and where said remote information may be of the following types: driving directions, weather reports, traffic conditions and routing, business data, location based services data.

6. A mobile display system according to claim 5 and wherein said mobile communicator at least comprise of a GPS or connected to a GPS.

7. A mobile display system according to claim 1 and wherein said Head Up Display apparatus comprises of a light source; an image source coupled to the light source; A refractive lens reflecting light rays from the image source for displaying to the driver of said vehicle.

8. A mobile display system according to claim 7 and wherein said refractive lens has an optical gain and wherein said light source changes its intensity according to said vehicles driver's field of view light conditions

9. A mobile display system according to claim 7 and wherein said Head Up Display apparatus is being capable of modifying image of information received from said mobile communicator to match said image source.

10. A mobile display system according to claim 3 and wherein said wireless communication network is at least one of the following wireless technologies: Bluetooth, Wi-Fi, WiMax, UWB, NFC, wireless USB,

11. A mobile display system according to claim 1 and wherein said link between said mobile communicator and said Head Up Display apparatus is at least one of the following wired links technologies: serial, USB, USB2GO, 12C, CAN BUS, parallel link.

12. A mobile display system according to claim 1 and wherein said wireless inputs means is at least one of the following wireless technologies: RF, IR, acoustic waves.

13. A mobile display system according to claim 7 and wherein said refractive lens can be operative in at least two positions wherein at least one of said positions is within the line of sight of said vehicle operator and wherein moving between said positions is due to at least one of the following events: an event requiring to display information to said driver of said vehicle, receiving a call, dialing, user command, receiving information from said mobile communicator that requires to display information to said driver of the vehicle, a vehicle event, an event at surrounding of the vehicle, time elapses from last information display.

14. A mobile display system according to claim 1 and wherein said head up display apparatus can be in one of the following states: projecting an image, no projection; and wherein moving between said states is due to at least one of the following events: an event requiring to display information to said driver of said vehicle, receiving a call, dialing, user command, receiving information from said mobile communicator that requires to display information to said driver of the vehicle, a vehicle event, an event at surrounding of the vehicle, time elapses from last information display.

15. A mobile display system according to claim 7 and wherein said refractive lens can be detached due to at least excessive mechanical power applied.

16. A mobile display system according to claim 7 and wherein said head up display apparatus can be attached, or built in at least one of the following vehicle apparatuses: dashboard, sun visor, back mirror.

17. A mobile display system according to claim 7 and wherein said head up display apparatus also communicates with at least a car kit, or headset

18. A mobile display system according to claim 17 and wherein said communication between head up display apparatus and car kit, or headset is a wireless communication.

19. In a mobile communications environment, a mobile communication and display system comprising:
a Head Up Display apparatus operative to display augmented information within field of view of the eyes the vehicle operator;
a mobile communicator in communication with a wireless communication network
an internal link between said mobile communicator and said Head Up Display apparatus;
Inputs means operative by said vehicle operator operative to control said mobile communicator; and
wherein said Head Up Display apparatus is being capable of displaying information of said mobile communicator; and
at least said mobile communicator is capable of retrieving remote information from said wireless network and pass it to said Head Up Display apparatus.

20. A mobile communication and display system according to claim 19 and wherein said mobile communicator is a cellular apparatus.

21. A mobile communication and display system according to claim 19 and wherein said wireless communication network is at least one of the following wireless technologies: Bluetooth, Wi-Fi, WiMax, UWB, NFC, wireless USB.

22. A mobile communication and display system according to claim 19 and wherein said mobile communicator at least comprise of a GPS or connected to a GPS.

23. A Head Up Display apparatus for providing augmented wireless information to a driver of a vehicle, comprising: white light source; a diffuser; a LCD operative in a transitive mode; a visor operative to reflect specific light waves and transfer all other waves lengths

24. A Head Up Display apparatus according to claim 23 wherein said LCD functions as shutter in various shape and color and wherein said visor is coated with selectively reflective in the same color, which the image is generated at said image source LCD;

25. A Head Up Display apparatus according to claim 23 wherein said LCD functions as shutter in various colors and wherein different color images are displayed in a time domain multiplexing and wherein said visor is coated with selectively reflective in the same color, which the image is generated at said image source LCD;
